(19) United States
(12) Patent Application Publication
(10) Pub. No.: US 2010/0130010 A1
(43) Pub. Date: May 27, 2010

(54) METHOD OF FABRICATING SEMICONDUCTOR DEVICE UNCONSTRAINED BY OPTICAL LIMIT AND APPARATUS OF FABRICATING THE SEMICONDUCTOR DEVICE

(75) Inventors: Sahnggi PARK, Daejeon (KR); Kap-Joong Kim, Daejeon (KR); In-Gyoo Kim, Daejeon (KR); Gyungock Kim, Seoul (KR)

Correspondence Address: AMPACC Law Group, 3500 188th Street S.W., Suite 103, Lynnwood, WA, 98037, US

(73) Assignee: Electronics and Telecommunications Research Institute, Daejeon (KR)

(21) Appl. No.: 12/538,080

(22) Filed: Aug. 7, 2009

(30) Foreign Application Priority Data
Nov. 25, 2008 (KR) 10-2008-0117279

(51) Int. Cl. H01L 21/308; G01B 11/27

(52) U.S. Cl. 438/689; 356/400; 257/E21.235

(57) ABSTRACT

Provided are a method of fabricating a semiconductor device unconstrained by optical limit and an apparatus of fabricating the semiconductor device. The method includes: forming an etch target layer on a substrate; forming a hard mask layer on the etch target layer; forming first mask patterns on the hard mask layer; forming first spacers on sidewalls of the first mask patterns; forming hard mask patterns having an opening by using the first mask patterns and the first spacers as a mask to etch the hard mask layer; aligning second mask patterns on the hard mask patterns to fill the opening; forming second spacers on sidewalls of the second mask patterns; forming fine mask patterns by using the second mask patterns and the second spacers as a mask to etch the hard mask patterns; and forming fine patterns by using the fine mask patterns as a mask to etch the etch target layer.

### CROSS-REFERENCE TO RELATED APPLICATIONS

This U.S. non-provisional patent application claims priority under 35 U.S.C. §119 of Korean Patent Application No. 10-2008-0117279, filed on Nov. 25, 2008, the entire contents of which are hereby incorporated by reference.

### BACKGROUND

The present invention disclosed herein relates to a method of fabricating a semiconductor device, and more particularly, to a method of fabricating a semiconductor device unconstrained by optical limit and an apparatus of fabricating the semiconductor device.

Semiconductor fine processes have been developed together with the progress of photolithography technology. Especially, in an aspect of the level of technology, the minimum line width of 100 nm to 200 nm in 1990 has been advanced into the minimum line width of less than 100 nm in 2000. That is, nanotechnology comes into the actual competitive time.

The wavelength of light injected during a photolithography process is the most important factor for determining a fine line width. Mercury g-line and i-line lamps have wave lengths of 436 nm and 365 nm, respectively, and are currently extensively used. However, there is limitation in realizing a line width of less than 0.3 nm. A light source used for a line width of 100 nm to 300 nm generally is a Krf excimer laser of 248 nm. In the 2000s, an ArF excimer laser of 193 nm is used in realizing a nano line width of less than 100 nm.

If a line width is far greater than the wavelength of a light source, there is no great difficulty in projecting a mask pattern on a wafer even when a projection system of a relatively low technological level is used. However, if a line width is similar or less than the wavelength of a light source, because of diffraction and interference of light, it is hard to achieve a clear pattern on a wafer and it also requires a complex projection system. Especially, if the pitch is similar to or less than the wavelength of a light source, it requires a projection system of a very high technological level and complex computer modeling technology.

As a result, optical limit originating from the wavelength of a light source will remain if a light source of a shorter wavelength is not developed. Although years of efforts are made on laser development to utilize a shorter wavelength than the 193 nm ArF excimer laser, there is no significant progress. This is due to the progress of an emitter material emitting light and also fundamental characteristics such as high absorption and aberration of material generated in deep UV. A 150 nm pitch is already close to the optical limit of a 193 nm light source. The optical limit due to the wavelength of a light source will remain for a long time even when technology is currently being advanced. That is, it is hard to expect a great deal of advancement in a short time.

### SUMMARY

The present invention provides a method of fabricating a semiconductor device unconstrained by optical limit and an apparatus of fabricating the semiconductor device.

Embodiments of the present invention provide methods of fabricating a semiconductor device unconstrained by optical limit including: forming an etch target layer on a substrate; forming a hard mask layer on the etch target layer; forming first mask patterns on the hard mask layer; forming first spacers on sidewalls of the first mask patterns; etching the hard mask layer using the first mask patterns and the first spacers as a mask to form hard mask patterns having an opening; aligning second mask patterns on the hard mask patterns to fill the opening; forming second spacers on sidewalls of the second mask patterns; etching the hard mask patterns using the second mask patterns and the second spacers as a mask to form fine mask patterns; and etching the etch target layer using the fine mask patterns as a mask to form fine patterns.

In some embodiments, a width of the fine pattern is less than the minimum line width defined by a photolithography process.

In other embodiments, a pitch of the fine patterns is substantially identical to the half of a pitch of the first mask patterns and a pitch of the second mask patterns.

In still other embodiments, the first mask patterns and the second mask patterns are defined by a photolithography process.

In even other embodiments, the forming of the first spacers includes: forming an insulation spacer on sidewalls of the first mask patterns; and reducing a width of the insulation spacer by performing an etching process on the insulation spacer.

In yet other embodiments, the forming of the second spacers includes: forming an insulation spacer on sidewalls of the second mask patterns; and reducing a width of the insulation spacer by performing an etching process on the insulation spacer.

In further embodiments, the first mask pattern, the second mask pattern, the first spacer, and the second spacer have an etch selectivity with respect to the hard mask layer and the fine mask pattern.

In still further embodiments, a lower width of the first spacer is substantially identical to a lower width of the second spacer.

In other embodiments of the present invention, apparatuses of fabricating a semiconductor device unconstrained by optical limit include: an alignment reflecting mirror adjusting alignment between an alignment mark of a reticle and an alignment mark of a wafer; a light emitting unit emitting laser beam to the alignment reflecting mirror; and a detection unit receiving beam reflected from the alignment reflecting mirror to detect whether the reticle is aligned with the wafer or not.

In some embodiments, the apparatuses further include an optical table equipped with the alignment reflecting mirror, the light emitting unit, and the detection unit.

In other embodiments, the apparatuses further include a pair of magnification reflecting mirrors receiving the beam reflected from the alignment reflecting mirror to output laser beam to the detection unit.

In still other embodiments, the magnification reflecting mirror repetitively reflects the beam reflected from the alignment reflecting mirror to magnify an alignment error.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIGS. 1A through 3 are sectional views illustrating a method of fabricating a semiconductor device unconstrained by optical limit according to an embodiment of the present invention; and

FIGS. 4 through 6 are views illustrating an apparatus of fabricating a semiconductor device unconstrained by optical limit according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

In the figures, each component may be exaggerated for clarity. Like reference numerals refer to like elements throughout.

Hereinafter, numerical values are limited with respect to line widths or pitches of patterns but are used as just examples to make those skilled in the art understand clearly the present invention without difficulties. Accordingly, numeral values about patterns do not limit the technical scope of the present invention.

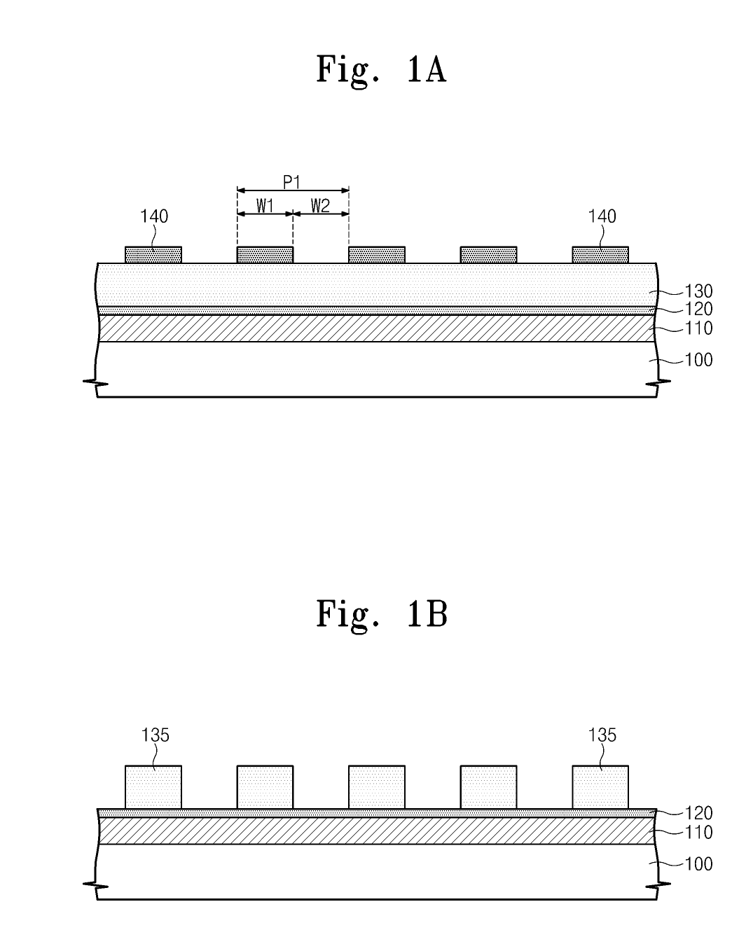

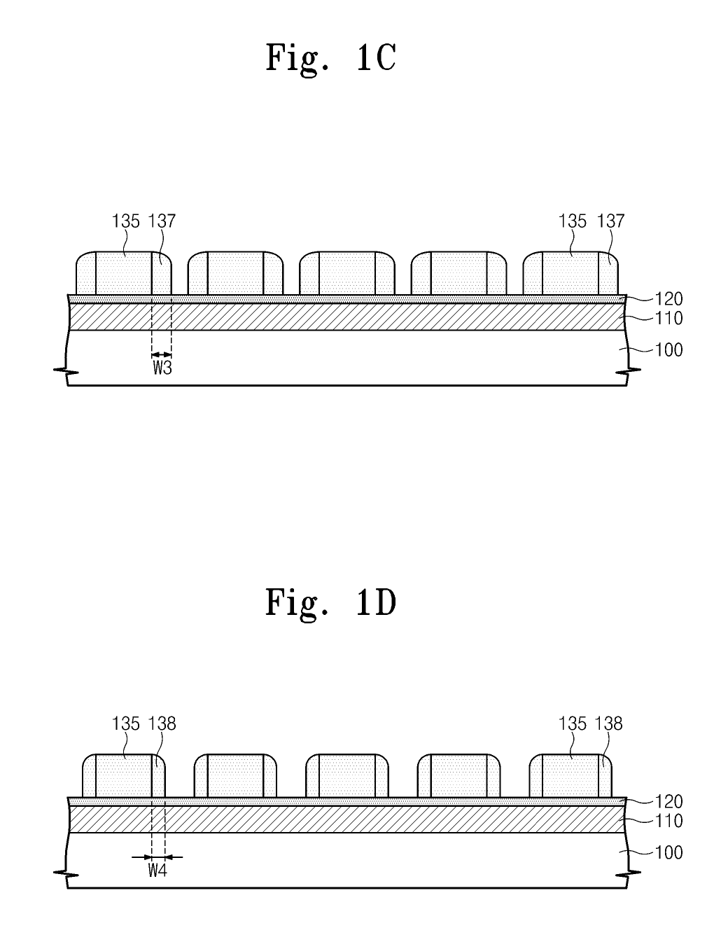

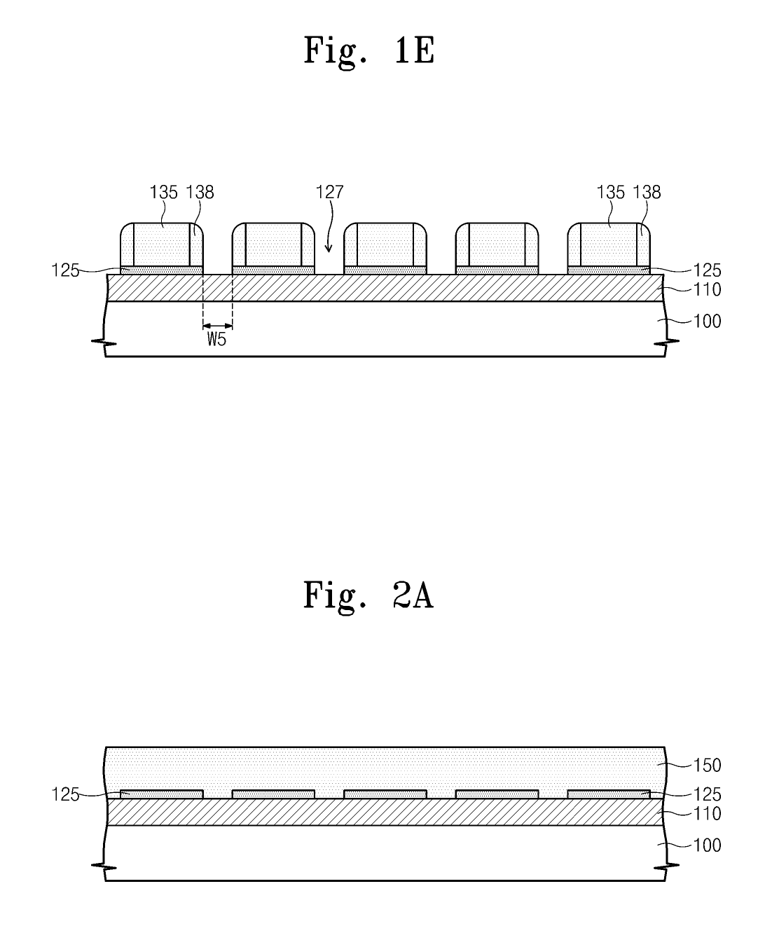

FIGS. 1A through 3 are sectional views illustrating a method of fabricating a semiconductor device unconstrained by optical limit according to an embodiment of the present invention.

Referring to FIG. 1A, an etch target layer 110 is formed on a substrate 100. The etch target layer 110 may be a silicon layer. The silicon layer may have a thickness of about 100 nm. A hard mask layer 120 and a first mask layer 130 are sequentially formed on the etch target layer 110. The first mask layer 130 may have an etch selectivity with respect to the hard mask layer 120. For example, when a has an etch selectivity with respect to b, it means that a is etched at the maximum and b is etched at the minimum or vice versa. For example, the first mask layer 130 may be a silicon oxide layer and the hard mask layer 120 may be a silicon nitride layer.

A first photoresist pattern 140 is formed on the first mask layer 130. The first photoresist patterns 140 may have the minimum line width defined by a photolithography process. For example, the pitch P1 of the first photoresist pattern 140 may be about 140 nm. Additionally, the first photoresist patterns 140 may have a line width W1 of about 70 nm and the interval W2 between the first photoresist patterns 140 may be about 70 nm.

Referring to FIG. 1B, an etching process is performed on the first mask layer 130 using the first photoresist patterns 140 as a mask in order to form a first mask pattern 135 on the hard mask layer 120. The etching process may be an anisotropic etching process.

Referring to FIG. 1C, an insulation spacers 137 are formed on the both sidewalls of the first mask pattern 135. The insulation spacer 137 may be formed by forming an insulation layer to cover the first mask pattern 135 and then performing an anisotropic etching process on the insulation layer. The insulation spacer 137 may be formed of the same material as the first mask pattern 135. For example, the insulation spacer 137 may be formed of a silicon oxide layer. The width W3 of the insulation spacer 137 may be about 25 nm. Accordingly, the interval exposing the hard mask layer 120 between the insulation spacers 137 may be about 20 nm.

Referring to FIG. 1D, a first spacer 138 is formed by performing an etching process on the insulation spacer 137 to reduce the width W3 of the insulation spacer 137. The etching process may be an isotropic etching process. Accordingly, the width W4 of the first spacer 138 may be less than the width W3 of the insulation spacer 137. This is to reduce the line widths of fine mask patterns that will be described below. For example, the width W4 of the first spacer 138 may be about 15 nm.

Referring to FIG. 1E, the hard mask layer 120 is etched using the first mask pattern 135 and the first spacer 138 as an etch mask in order to form hard mask patterns 125 having an opening 127. The width W5 of the opening 127 may be about 40 nm. As illustrated in FIGS. 1A through 1E, the series of processes may be called as a first photolithography process and a first etching process.

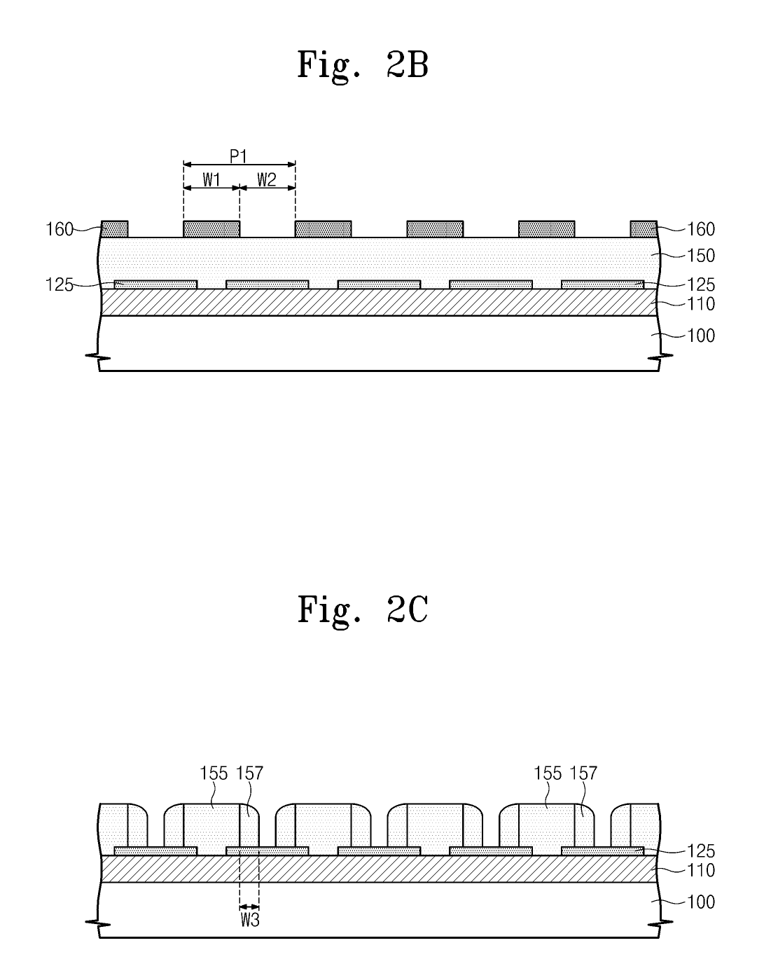

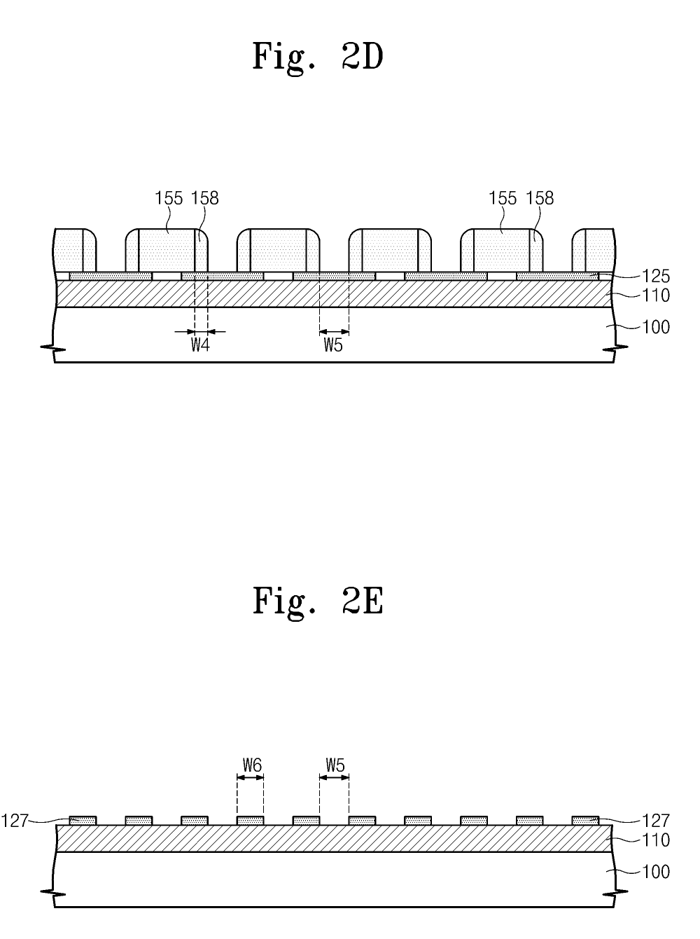

Referring to FIG. 2A, a second mask layer 150 is formed on the hard mask patterns 125 to fill the opening 127. Before the forming of the second mask layer 150, the first mask pattern 135 and the first spacer 138 may be removed. The second mask layer 150 may have an etch selectivity with respect to the hard mask patterns 125. For example, the second mask layer 150 may be a silicon oxide layer and the hard mask patterns 125 may be a silicon nitride layer.

Referring to FIG. 2B, a second photoresist pattern 160 is formed on the second mask layer 150. The second photoresist pattern 160 has the minimum line width defined by a photolithography process. For example, the pitch P1 of the second photoresist patterns 160 may be about 140 nm. Additionally, the width W1 of the second photoresist pattern 160 may be about 70 nm and the interval W2 between the second photoresist patterns 160 may be about 70 nm.

The second photoresist patterns 160 are formed to be aligned with the hard mask patterns 125. In more detail, the center axis of the second photoresist pattern 160 is aligned with the middle between the hard mask patterns 125. As a result, the second photoresist patterns 160 are aligned being deviated from the hard mask patterns 125. This is the same meaning that the second photoresist patterns 160 are aligned with the first photoresist patterns 140. An alignment error of the second photoresist patterns 160 and the first photoresist patterns 140 may be ±1.5 nm.

Referring to FIG. 2C, an etching process is performed on the second mask layer 150 using the second photoresist patterns 160 as a mask in order to form second mask patterns 155 on the hard mask patterns 125. The etching process may be an anisotropic etching process. Insulation spacers 157 are formed on the both sidewalls of the second mask pattern 155. The insulation spacer 157 may be formed by forming an insulation layer to cover the second mask patterns 155 and then performing an anisotropic etching process on the insulation layer. The insulation spacer 157 may be formed of the same material as the second mask pattern 155. For example, the insulation spacer 157 may be formed of a silicon oxide layer. The width W3 of the insulation spacer 157 may be about 25 nm. Accordingly, the interval W5 exposing the hard mask pattern 125 between the insulation spacers 157 may be about 20 nm.

Referring to FIG. 2D, a second spacer 158 is formed by performing an etching process on the insulation spacer 157 to reduce the width W3 of the insulation spacer 157. The etching process may be an isotropic etching process. Accordingly, the width W4 of the second spacer 158 may be less than the width W3 of the insulation spacer 157. This is to reduce the line widths of fine mask patterns that will be described below. For example, the width W4 of the second spacer 158 may be about 15 nm. The lower width W4 of the second spacer 158 may be the same as the lower width W4 of the first spacer 138.

Referring to FIG. 2E, the hard mask patterns 125 are etched using the second mask pattern 155 and the second spacer 158 as an etching mask in order to form fine mask patterns 127. The width W6 of the fine mask pattern 127 may be less than the minimum line width defined by a photolithography process. The interval W5 between the insulation spacers 157 may define the interval W5 of the fine mask patterns 127. As illustrated in FIGS. 2A through 2E, the series of processes may be called as a second photolithography process and a second etching process.

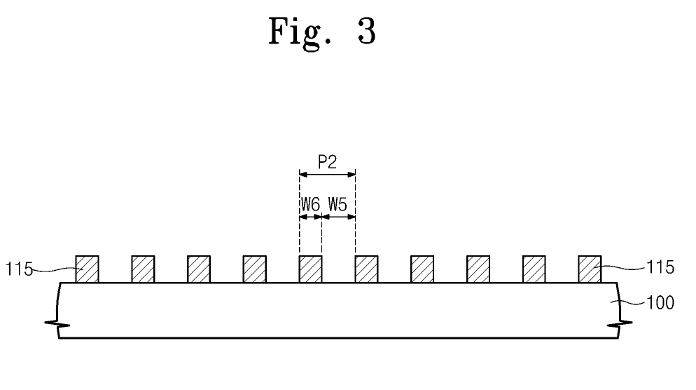

Referring to FIG. 3, the etch target layer 110 is etched using the fine mask patterns 127 as a mask in order to form fine patterns 115. The line width W6 of the fine pattern 115 is less than the minimum line width defined by a photolithography process. The line width W6 of the fine pattern 115 and the interval W5 between the fine patterns 115 constitute the pitch P2 of the fine patterns 115. The pitch P2 of the fine patterns 115 may be substantially identical to the half of the pitch P1 of the first photoresist patterns 140 and the pitch P1 of the second photoresist patterns 160. Additionally, the pitch P2 of the fine patterns 115 may be substantially identical to the half of the pitch P1 of the first mask patterns 135 and the pitch P1 of the second mask patterns 155. For example, the line width W6 of the fine patterns 115 may be about 30 nm and the interval W5 between the fine patterns 115 may be about 40 nm.

Through the two times repetitive photolithography processes and etching processes (i.e., the first photolithography process and the first etching process, and the second photolithography process and the second etching process) described in FIGS. 1A through 3, fine patterns 115 unconstrained by optical limit are formed. In order to form a fine pattern having a smaller line width, the lithography process and the etching process may be repeatedly performed n-times (n is a positive integer). Additionally, characteristics of a silicon optical waveguide device can be improved by realizing a fine line width according to the embodiment of the present invention.

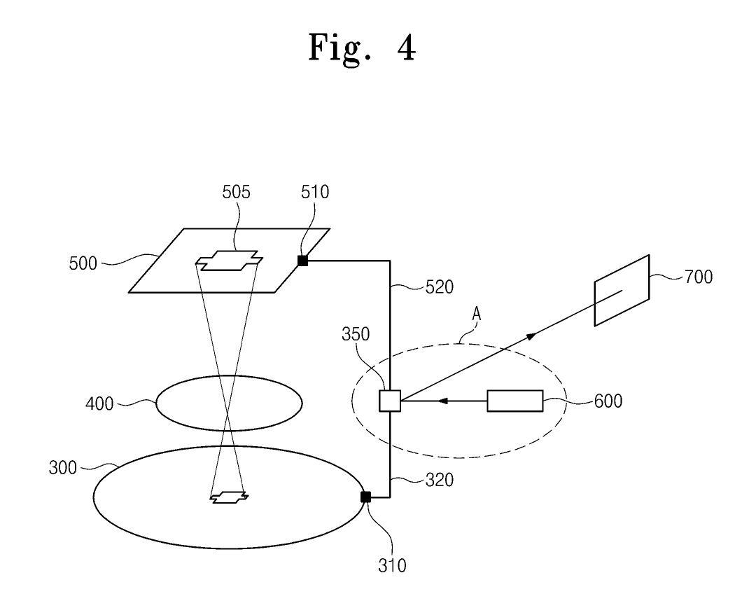

FIGS. 4 through 6 are views illustrating an apparatus of fabricating a semiconductor device unconstrained by optical limit according to an embodiment of the present invention.

The drawings illustrates an apparatus for aligning the first mask patterns and the second mask patterns of the above-mentioned embodiment within an alignment error range of about ±1.5 nm. The typical lithography equipment uses an optical microscope for alignment but cannot be used in the above-mentioned embodiment because its alignment error is more than several hundreds of nanometers. In order to realize an ultrafine size of a line width and a pitch unconstrained by optical limit using at least two masks, the present invention includes an alignment device below.

Referring to FIG. 4, a reticle pattern 505 of a reticle 500 is transferred on a wafer 300 through a lens 400. An alignment mark 310 of the wafer 300 may be in a scribe line. The wafer 300 is aligned and fixed using the alignment mark 310 of the wafer 300 and an alignment mark 510 of the reticle 500.

The alignment mark 310 of the wafer 300 is coupled and fixed to a first alignment reference part 320, and the alignment mark 510 of the reticle 500 is coupled and fixed to a second alignment reference part 520. Whether it is aligned or not is determined using an alignment reflecting mirror 350 disposed between the first alignment reference part 320 and the second alignment reference part 520. In more detail, whether it is aligned or not is determined using a light emitting unit 500 emitting laser beam on the alignment reflecting mirror 350 and a detection unit 700 for receiving light reflected from the alignment reflecting mirror 350.

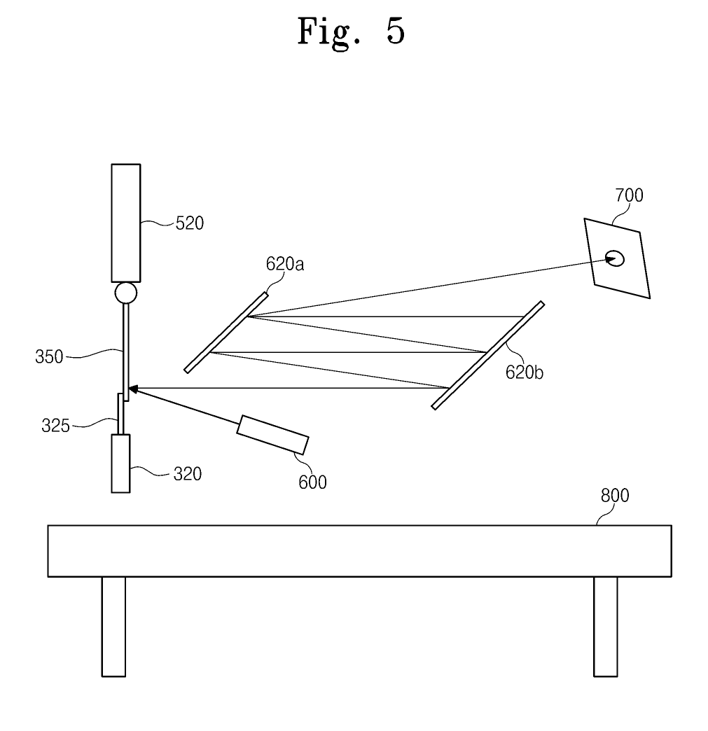

A portion A of FIG. 4 will be described in more detail with reference to FIG. 5. An alignment reflecting mirror 350, a light emitting unit 600, magnification reflecting mirrors 620a and 620b, and a detection unit 700 are loaded into an optical table 800. The optical table 800 prevents external vibration. A fixing unit 325 is mounted on the first alignment reference unit 320 and the alignment reflecting mirror 350 is mounted on a second alignment reference unit 520. A laser beam emitted from the light emitting unit 600 is reflected by the alignment reflecting mirror 350 and then outputted to the pair of magnification reflecting mirrors 620a and 620b. An alignment error is increased when the laser beam is repeatedly reflected between the pair of magnification reflecting mirrors 620a and 620b. That is, the magnification reflecting mirrors 620a and 620b increase a progression path of the laser beam through repetitive reflections. In order to measure an alignment error, the laser beam that are repetitively reflected between the pair of magnification reflecting mirrors 620a and 620b is outputted to the detection unit 700.

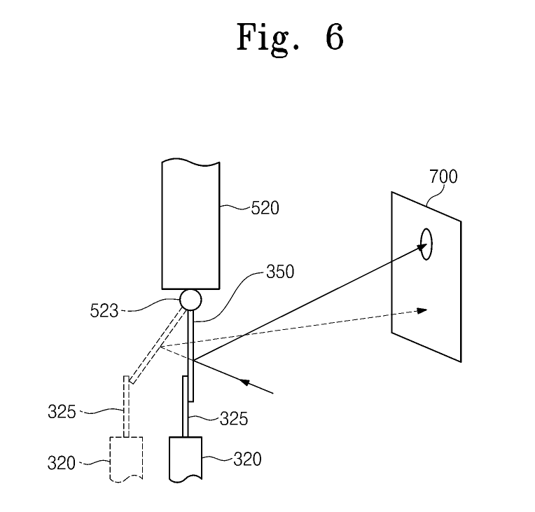

Referring to FIG. 6, a principle of magnifying an alignment error will be described in more detail. The alignment reflecting mirror 350 is mounted on the second alignment reference unit 520 through a connection member 523. The connection member 523 provides a function for allowing the alignment reflecting mirror 350 to move in a circuit through a mechanical power applied by the fixing unit 325.

The alignment reflecting mirror 350, the fixing unit 325, and the first alignment reference unit 320, indicated with a solid line, represent a case that an alignment error is minimized. The alignment reflecting mirror 350, the fixing unit 325, and the first alignment reference unit 320, indicated with a dotted line, represent a case that an alignment error is beyond an allowable critical value. In order to align a pattern (i.e., the above mentioned second mask pattern 505) of the reticle with a pattern formed on the wafer 300, the alignment reflecting mirror 350 outputs a laser beam to the detection unit 700 at a specific angle (e.g., in a vertical state (the solid line of FIG. 6)) to set up a reference point. The second mask patterns or the other mask patterns have an alignment error of zero when the laser beam points to the reference point exactly. If alignment is inaccurate, the laser beam reflected by the alignment reflecting mirror 350 has an alignment error that is increased due to the magnification reflecting mirrors 620a and 620b. Additionally, when it is confirmed by the detection unit 700 that an alignment error is within an allowable range, the wafer 300 or the reticle 500 does not move in a parallel direction (an arrow →) and is fixed for completing an alignment process. If the distance of the magnification path is sufficiently enough, though the diameter of the laser beam is about 1 mm, the alignment error can be magnified for recognition. An alignment error of less than 1 nm can be accomplished. For example, if the length of the alignment reflecting mirror 350 is about 1 cm and its magnification distance is 10 km, the alignment error of 1 nm is magnified into the size of 1 mm. Therefore, the laser beam having the diameter of 1 mm can be identified.

The optical microscope used for alignment during an exposure process has about 1000 times magnification at the maximum. When the optical microscope is used, since a line having a line width of 1 μm can be seen as the size of 1 mm, it is difficult to expect accuracy of less than 100 nm. Referring to FIG. 2B, when it is assumed that allowable limit of 10 % is used in order to realize a fine line width of 30 nm, it requires an alignment accuracy range of ±1.5 nm. This is impossible if the optical microscope is used. Accordingly, according to the embodiment of the present invention, an alignment error can be optimized with accuracy of less than 1 nm through an alignment device using laser beam.

According to the embodiment of the present invention, when the second photoresist pattern 160 of FIG. 2B is aligned, the apparatus of fabricating the semiconductor device is used. Accordingly, an alignment process can be performed using laser beam and the repetitive photolithography process can be performed without being deviated from a critical tolerance value.

According to the embodiment of the present invention, provided is a method of fabricating a semiconductor device unconstrained by optical limit. Through repetitive photolithography process and etching process, it is possible to form a fine pattern having a smaller pitch than optical limit. Additionally, since an alignment process is performed using laser beam, a repetitive photolithography process can be performed without being deviated from a critical error value.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of fabricating a semiconductor device unconstrained by optical limit, the method comprising:
forming an etch target layer on a substrate;
forming a hard mask layer on the etch target layer;
forming first mask patterns on the hard mask layer;
forming first spacers on sidewalls of the first mask patterns;
etching the hard mask layer using the first mask patterns and the first spacers as a mask to form hard mask patterns having an opening;
aligning second mask patterns on the hard mask patterns to fill the opening;
forming second spacers on sidewalls of the second mask patterns;
etching the hard mask patterns using the second mask patterns and the second spacers as a mask to form fine mask patterns; and
etching the etch target layer using the fine mask patterns as a mask to form fine patterns.

2. The method of claim 1, wherein a width of the fine pattern is less than the minimum line width defined by a photolithography process.

3. The method of claim 1, wherein a pitch of the fine patterns is substantially identical to the half of a pitch of the first mask patterns and a pitch of the second mask patterns.

4. The method of claim 1, wherein the first mask patterns and the second mask patterns are defined by a photolithography process.

5. The method of claim 1, wherein the forming of the first spacers comprises:
forming an insulation spacer on sidewalls of the first mask patterns; and
reducing a width of the insulation spacer by performing an etching process on the insulation spacer.

6. The method of claim 1, wherein the forming of the second spacers comprises:
forming an insulation spacer on sidewalls of the second mask patterns; and
reducing a width of the insulation spacer by performing an etching process on the insulation spacer.

7. The method of claim 1, wherein the first mask pattern, the second mask pattern, the first spacer, and the second spacer have an etch selectivity with respect to the hard mask layer and the fine mask pattern.

8. The method of claim 1, wherein a lower width of the first spacer is substantially identical to a lower width of the second spacer.

9. An apparatus of fabricating a semiconductor device unconstrained by optical limit, the apparatus comprising:
an alignment reflecting mirror adjusting alignment between an alignment mark of a reticle and an alignment mark of a wafer;
a light emitting unit emitting a laser beam to the alignment reflecting mirror; and
a detection unit receiving the laser beam reflected from the alignment reflecting mirror to detect whether the reticle is aligned with the wafer or not.

10. The apparatus of claim 9, further comprising an optical table equipped with the alignment reflecting mirror, the light emitting unit, and the detection unit.

11. The apparatus of claim 9, further comprising a pair of magnification reflecting mirrors receiving the beam reflected from the alignment reflecting mirror to output laser beam to the detection unit.

12. The apparatus of claim 11, wherein the magnification reflecting mirror repetitively reflects the beam reflected from the alignment reflecting mirror to magnify an alignment error.
